(19) United States
(12) Patent Application Publication
(10) Pub. No.: US 2017/0051165 A1
(43) Pub. Date: Feb. 23, 2017

(54) CONDUCTIVE PASTE, METHOD OF PREPARATION, AND SOLAR CELL ELECTRODE USING THE SAME

(71) Applicant: SHIN-ETSU CHEMICAL CO., LTD., Tokyo (JP)

(72) Inventors: Hiroto Ohwada, Annaka-shi (JP); Kazuyuki Matsumura, Annaka-shi (JP); Hideki Sugahara, Annaka-shi (JP); Yoshiteru Sakatume, Annaka-shi (JP)

(73) Assignee: SHIN-ETSU CHEMICAL CO., LTD., Tokyo (JP)

(21) Appl. No.: 15/235,739

(22) Filed: Aug. 12, 2016

(30) Foreign Application Priority Data
Aug. 17, 2015 (JP) 2015-160562

(51) Int. Cl. C09D 7/12; C09D 7/14; C03C 8/18; C03C 8/10; H01L 31/0216; H01L 31/0224; H01L 31/18; H01L 31/028; H01L 31/068; C09D 5/24; C03C 4/14

(52) U.S. Cl. CPC C09D 7/1275; C09D 5/24; C09D 7/14; C03C 8/18; C03C 8/10; C03C 4/14; H01L 31/022425; H01L 31/1864; H01L 31/028; H01L 31/0682; H01L 31/02168; C03C 2204/00; C03C 2205/00

(57) ABSTRACT

A conductive paste includes electrically conductive particles, a binder, an organic solvent, a glass powder, and a specific amount of inorganic oxide particles that are at least partially surface-coated with an organophosphorus compound and have a specific average particle size. Solar cell electrodes formed by firing the conductive paste have increased bond strength with a substrate.

### CROSS-REFEFFNCE TO RELATED APPLICATION

This non-provisional application claims priority under 35 U.S.C. §119(a) on Patent Application No. 2015-160562 filed in Japan on Aug. 17, 2015, the entire contents of which are hereby incorporated by reference.

### TECHNICAL FIELD

This invention relates to a conductive paste that is effective for fabricating solar cell electrodes, a method for preparing the conductive paste, and a solar cell electrode in which the conductive paste is used.

### BACKGROUND ART

Solar cells that use a crystalline silicon substrate have a construction in which an n+ layer is formed on one side of the silicon substrate and a p+ layer is formed on the other side, an anti-reflective coating made of silicon nitride or titanium oxide is formed on the surface of the silicon substrate, and an electrode composed mainly of silver is formed on top of the anti-reflective coating. A fire-through process is primarily used as the method of formation, both for light-receiving surface and back surface electrodes. The fire-through process applies an electrode paste onto the anti-reflective coating or silicon substrate, and fires the paste to form an electrode.

The electrode paste is composed primarily of an electrically conductive powder and other ingredients such as a glass powder, a binder and an organic solvent (see JP-A 2014-033036 and JP-A 2006-332032).

In the electrode paste firing operation, the glass powder included in the electrode paste melts and penetrates the anti-reflective coating, and the electrically conductive ingredient (i.e., the electrically conductive powder) forms an ohmic contact with an n+ layer and a p+ layer in the silicon substrate.

Solder-coated metal wires called “interconnectors” are heat-bonded to collecting electrodes called “busbars” formed on the light-receiving surfaces and back surfaces of solar cells thus obtained, and thereby connect the cells to one another.

When the busbars lack a sufficient bond strength to the silicon substrate, the busbars may peel from the silicon substrate or peeling may gradually proceed during long-term outdoor exposure, lowering the power output of the cell. Nor is this problem limited to the busbars; when the bond strength between the cell electrodes and the silicon substrate is insufficient, this may lead to a decrease in power output due to, for example, the influence of encapsulants during modularization (see JP-A 2011-012243).

Approaches which, based on studies of glass powder types, addresses such problems by increasing the fire-through properties of the glass powder or increasing the bond strength between the cell electrode and the silicon substrate include methods that, for example, use glass powder having a high softening point and raise the firing temperature see JP-A 2008-543080 and JP-A 2010-087501).

When the fire-through properties are increased, one drawback is that the glass component formed by melting of the class powder tends to have inadequate durability. Another drawback is that powder having a high softening point results in excellent durability of the corresponding glass component, but the firing temperature must be raised, as a result of which the power output of the solar cell decreases.

### CITATION LIST

Patent Document 1: JP-A 2014-033036

Patent Document 2: JP-A 2006-332032

Patent Document 3: JP-A 2011-012243

Patent Document 4: JP-A 2008-543080

Patent Document 5: JP-A 2010-087501

### DISCLOSURE OF INVENTION

It is therefore an object of this invention to provide a conductive paste that gives electrodes formed by firing the conductive paste an improved bond strength with a substrate and, more specifically, makes it possible to improve the bond strength between a solar cell electrode and a silicon substrate, improve the solar cell power output, and improve the long-term reliability of the solar cell electrode. Further objects of the invention are to provide a method of preparing such as conductive paste, and to provide a solar cell electrode in which such a conductive paste is used.

As a result of extensive investigations, the inventors have discovered that by adding an organophosphorus compound-coated inorganic oxide to a conductive paste containing electrically conductive particles, a binder, an organic solvent and a glass powder, the dispersibility of the glass powder improves, in addition to which a thermal melt-promoting effect is obtained. Hence, even when a glass powder having a high softening point is used, the fire-through properties improve without raising the firing temperature to any large degree, thus improving the power output at the solar cell. At the same time, a satisfactory bond strength between the electrode and the silicon substrate is obtained, in addition to which ohmic contact at the interface between the solar cell electrode and the layer of the silicon substrate improves due to the phosphorus ingredient, enabling a further increase in solar cell power output.

Accordingly, in one aspect, the invention provides a conductive paste containing electrically conductive particles, a binder, an organic solvent, a glass powder, and inorganic oxide particles that are at least partially surface-coated with an organophosphorus compound and have an average particle size for primary particles thereof, expressed as the volume base median diameter, of from 0.01 to 5 μm, the inorganic oxide particles being included in an amount of from 0.1 to 7.0 wt % based on the total weight of the conductive paste. The inorganic oxide particles are preferably hydrophobic spherical silica fine particles.

Typically, the inorganic oxide particles that are at least partially surface-coated with an organophosphorus compound are hydrophobic spherical silica fine particles which are obtained by hydrolytically condensing a tetrafunctional silane compound, a partial hydrolytic condensate of a tetrafunctional silicone compound, or a mixture thereof to form hydrophilic spherical silica fine particles and introducing R¹SiO_{3/2} units (wherein R¹ is a substituted or unsubstituted monovalent hydrocarbon group of 1 to 20 carbon atoms) and R²₃SiO_{1/2} units (wherein each R² is independently a substituted or unsubstituted monovalent hydrocarbon group of 1 to 6 carbon atoms) onto surfaces of the hydrophilic spherical silica fine particles, and which are at least partially surface-coated with an organophosphorus compound.

The conductive paste is adapted for use in fabricating a solar cell electrode.

In another aspect, the invention provides a method for preparing a conductive paste, the method being characterized by producing hydrophobic spherical silica fine particles that are at least partially surface-coated with an organophosphorus compound and have an average particle size for primary particles thereof, expressed as the volume base median diameter, of from 0.01 to 5 μm, and mixing the organophosphorus compound-coated hydrophobic spherical silica fine particles, in an amount of from 0.1 to 7.0 wt % based on the total weight of the conductive paste, together with conductive particles, a binder, an organic solvent and a glass powder, wherein the organophosphorus compound-coated hydrophobic spherical silica fine particles are produced by a method comprising the steps of:

(A1) obtaining a mixed-solvent dispersion of SiO₂ unit-containing hydrophilic spherical silica fine particles by hydrolyzing and condensing, within a mixture of a hydrophilic organic solvent and water and in the presence of a basic substance, a tetrafunctional silane compound of general formula (I) below

Si(OR³)₄ (I)

(wherein each R³ is independently a monovalent hydrocarbon group of 1 to 6 carbon atoms), a partial hydrolyzate of the tetrafunctional silane compound, or a mixture thereof;

(A2) obtaining a mixed-solvent dispersion of hydrophobic spherical silica fine particles of a first type, referred to herein as “surface-hydrophobized spherical silica fine particles,” by adding to the mixed-solvent dispersion of hydrophilic spherical silica fine particles a trifunctional silane compound of general formula (II) below

R¹Si(OR⁴)₃ (II)

(wherein R¹ is a substituted or unsubstituted monovalent hydrocarbon group of 1 to 20 carbon atoms, and each R⁴ is independently a monovalent hydrocarbon group of 1 to 6 carbon atoms), a partial hydrolyzate of the trifunctional silane compound, or a mixture thereof and surface-treating the hydrophilic spherical silica fine particles so as to introduce R¹SiC_{3/2} units (wherein R¹ is as defined above) onto surfaces of the hydrophilic spherical silica fine particles;

(A3) obtaining a concentrated mixed-solvent dispersion of the surface-hydrophobized spherical silica fine particles by removing part of the hydrophilic organic solvent and the water from, and thus concentrating, the mixed-solvent dispersion of surface-hydrophobized spherical silica fine particles;

(A4) obtaining hydrophobic spherical silica fine particles of a second type, referred to herein as “hydrophobic spherical silica fine particles,” by adding a silazane compound of general formula (III) below

R²₃SiNHSiR²₃ (III)

(wherein each R² is independently a substituted or unsubstituted monovalent hydrocarbon group of 1 to 6 carbon atoms), a monofunctional silane compound of general formula (IV) below

R²₃SiX (IV)

(wherein R³ is as defined above and X is a hydroxyl group or a hydrolyzable group), or a mixture thereof to the concentrated mixed-solvent dispersion of surface-hydrophobized spherical silica fine particles and treating the surf ace-hydrophobized spherical silica fine particles so as to introduce R²₃SiO_{1/2} units (wherein R² is as defined above) onto the surfaces of the surface-hydrophobized spherical silica fine particles; and

(A5) obtaining hydrophobic spherical silica fine particles of a third type, referred to herein as “organophosphorus compound-coated hydrophobic spherical silica fine particles,” by dissolving an organophosphorus compound in a dispersion of the hydrophobic spherical silica fine particles so as to at least partially surface-coat the, hydrophobic spherical silica fine particles with the organophosphorus compound.

In yet another aspect, the invention provides a solar cell electrode which is a fired body of the foregoing conductive paste adapted for use in fabricating a solar cell electrode.

### ADVANTAGEOUS EFFECTS OF THE INVENTION

This invention is able to increase the bond strength with a substrate of an electrode formed by firing a conductive paste. By producing a solar cell using the conductive paste of the invention, the bond strength between a solar cell electrode and a silicon substrate is improved, enabling an improvement also in the long-term reliability of the solar cells following modularization. Moreover, by improving the bond strength, it is possible to lower the firing temperature while yet achieving a good bond strength between the solar cell electrode and the silicon substrate, thus enabling, as a secondary effect, the power output of the solar cell to be increased.

### DESCRIPTION OP THE PREFERRED EMBODIMENTS

The objects, features and advantages of the invention will become more apparent from the following detailed description.

The conductive paste of the invention is characterized by containing electrically conductive particles, a glass powder, a binder, an organic solvent, and inorganic oxide particles that are at least partially surface-coated with an organophosphorus compound and have an average particle size for primary particles thereof, expressed as the volume base median diameter, of from 0.01 to 5 μm, and is effective for use in fabricating solar cell electrodes. The ingredients in the paste are each described below.

### Electrically Conductive Particles

The electrically conductive particles may be a particulate material that generally exhibits electrical conductivity. Such conductive particles are exemplified by conductive powders of metals such as gold, silver, copper, tin, platinum or palladium. Illustrative examples include silver powder, silver alloy powder, copper powder, copper alloy powder, gold powder, lead powder, tin powder, platinum powder, palladium powder, aluminum powder, and solder particles. The use of silver powder or copper powder is preferred. Such electrically conductive particles may include impurities other than electrically conductive substances, provided that the electrical conductivity is not loss. The particle shape and particle production method are not particularly limited, although from the standpoint of dispersibility, and also ease of application or printability when forming an electrode pattern, particles which are flake-like or spherical and have an average particle size for primary particles thereof, expressed as the volume base median diameter, of from 0.1 to 5 μm, and especially from 0.5 to 2 μm, are preferred.

### Glass Powder

Examples of glass powders that may be used include, but are not limited to, lead glass powders (e.g., PbO—B₂O₃—SiO₂, PbO—B₂O₃—SiO₂—Li₂O, PbO—SiO₂—Li₂O and PbO—B₂O₃—Al₂O₃) and non-lead glass powders (e.g. Bi₂O₃—B₂O₃—SiO, Bi₂O₃—B₂O₃—Al₂O₃ and B₂O₃—SiO₂—Li₂O) Examples of the particle shape include, but are not particularly limited to, spherical and irregular shapes. The particle dimensions are also not particularly limited, although from the standpoint of dispersibility, and also ease of application or printability when farming an electrode pattern, the average particle size for primary particles, expressed as the volume base media diameter, is preferably from 0.1 to 10 μm, and especially from 1 to 3 μm.

When the conductive paste of the invention is used as a solar cell electrode formed by a fire-through process, the glass powder preferably has a softening point in the range of 300 to 600° C.

At a softening paint below 300° C., the durability of the glass powder in the firing step following electrode pattern formation tends to be inadequate. On the other hand, at a softening point above 600° C., only partial melting of the glass powder occurs in the firing step and a sufficient bond strength may not be obtained between the electrode and the silicon substrate. For this reason, it may be necessary to further increase the firing temperature, although exposure to elevated temperature sometimes results in a decrease in the solar cell power output and so is undesirable.

### Binder

The binder is used as a viscosity modifier for the conductive paste composition. For example, cellulose-based resins (e.g., ethyl cellulose, nitrocellulose) and (meth)acrylic resins (e.g., polymethyl acrylate, polymethyl methacrylate) may be used. Ethyl cellulose is preferred.

### Organic Solvent

As with the above binder, the organic solvent is used as a viscosity modifier for the conductive paste composition. For example, alcohols (e.g., α-terpineol) and ester (e.g., hydroxyl group-containing esters, butyl carbitol acetate, 2,2,4-trimethyl -1,3-pentanediol monoisobutyrate) may be used. α-Terpineol is preferred.

### Inorganic Oxide Particles

In the inorganic oxide particles which are at least partially surface-coated with an organophosphorus compound, the inorganic oxide may be, for example, silica, alumina, titania, ceria or zirconia.

In this invention, the inorganic oxide particles which are at least partially surface-coated with an organophosphorus compound have an average particle size for primary particles thereof, expressed as the volume base median diameter, of from 0.01 to 5 μm, and preferably from 0.01 to 0.5 μm. When the particle size is smaller than 0.01 μm, the fine particles agglomerate and have a poor dispersibility in the binder. On the other hand, when the particle size is larger than 5 μm, the inorganic oxide fine particles occupy much of the electrode surface, causing undesirable effects such as hindering the deposition of electrically conductive particles in conductive connection.

The organophosphorus compound used to coat the surfaces of the inorganic oxide particles is preferably a phosphate group-containing polymerizable monomer and/or a phosphate group-containing polymerizable monomer derivative. Such a phosphate group-containing polymerizable monomer and/or a phosphate group-containing polymerizable monomer derivative can be synthesized by, as with general acrylic monomers, a dehydration reaction or transesterification using an acrylic acid or methacrylic acid and a phosphate compound. Alternatively, these organophosphorus compounds may be acquired as commercial products.

Illustrative examples of the organophosphorus compound include the following commercial products:

CH₂═C(CH₃)COO(C₂H₄O)ₙP═O(OH)₂
(n=1; acid phosphoxy ethyl methacrylate):
   Phosmer™ M (Uni-Chemical Co. Ltd.),
   Kayamer PM-1 (Nippon Kayaku Co,. Ltd.),
   Light Ester P-M (Kyoeisha Chemical Co., Ltd.),
   NK Ester SA (Shin-Nakamura Chemical Co., Ltd.)
(n=2): Phosmer™ PE2 (Uni-Chemical Co., Ltd.)
(n=4 to 5; acid phoaphoxy polyoxyethylene glycol monomethacrylate):
   Phosmer™ PE (Uni-Chemical Co., Ltd.)
(n=8): Phosmer™ PE8 (Uni-Chemical Co., Ltd.)

[CH₂═C(CH₃)COO(C₂H₄O)ₙ]ₘP═O(OH)₃₋ₙ
(n=1, m=1 and 2 mixture):
   MR-200 (Daihachi Chemical industry Co., Ltd.)

CH₂═CHCOO(C₂H₄O)ₙP═O(OH)₂
(n=1) : Phosmer™ A (Uni-Chemical Co., LTD.),
   Light Ester P-A (Kyoeisha Chemical Co., Ltd.)

[CH₂═CHCOO(C₂H₄O)ₙ]ₘP═O(OH)₃₋ₘ
(n=1, m=1 and 2 mixture):
   AR-200 (Daihachi Chemical Industry Co., Ltd.)

CH₂═C(CH₃)COO(C₂H₄O)ₙP═O(OC₄H₉)₂
(n=1): MR-204 (Daihachi Chemical Industry Co., Ltd.)

CH₂═CHCOO(C₂H₄O)ₙP═O(OC₄H₉)₂
(n=1): AR-204 (Daihachi Chemical Industry Co., Ltd.)

CH₂═C(CH₃)COO(C₂H₄O)ₙP═O(OR₈H₁₇)₂
(n=1): MR-208 (Daihachi Chemical Industry Co., Ltd.)

CH₂═CHCOO(C₂H₄O)ₙP═O(OC₈H₁₇)₂
(n=1): AP-208 (Daillachi Chemical Industry Co., Ltd.)

CH₂═C(CH₃)COO(C₂H₄O)ₙP═O(OH)(ONH₃C₂H₄OH)
(n=1): Phosmer^{m}'MR (Uni-Chemical Co., Ltd.)

CH₂═C(CH₃)COO(C₂H₄O)ₙP═O(OH)(ONH(CH₃)₂C₂H₄OCOC(CH₃)═CH₂)
(n=1): Phosmer™ DM (Uni-Chemical Co., Ltd.)

CH₂═C(CH₃)COO(C₂H₄O)ₙP═O(OH)(ONH(C₂H₅)₂C₂H₄OCOC(CH₃)═CH₂)
(n=1): Phosmer™ DE (Uni-Chemical Co., Ltd.)

CH₂═CHCOO(C₂H₄O)ₙP═O(O-Ph)₂ (Ph stands for phenyl)
(n=1): AR-260 (Daihachi Chemical Industry Co., Ltd.)

CH₂═C(CH₃)COO(C₂H₄O)ₙP═O(O-Ph)₂
(n=1): MR-260 (Daihachi Chemical Industry Co., Ltd.)

[CH₂═CHCOO(C₂H₄O)ₙ]₂P═O(OC₄H₉)
(n=1): PS-A4 (Daihachi Chemical Industry Co., Ltd.)

[CH₂═C(CH₃)COO(C₃H₄O)ₙ]₂P═O(OH)
(n=1): MR-200 (Daihachi Chemical Industry Co., Ltd.), Kayamer PM-2 (Nippon Kayaku Co., Ltd.), Kayamer PM-21 (Nippon Kayaku Co., Ltd.)

[CH₂═CHCOO(C₂H₄O)ₙ]₃P═O
(n=1): Viscoat 3PA Osaka Organic Chemical Industry Ltd.)

Additional examples of available organophosphorus compounds include, but are not limited to, those for which the average value of the ethylene oxide chain length n in the above formulas is n=0, 2 to 8, 14. 23, 40 and 50. Two or more organophosphorus compounds may be mixed and used in any ratio.

The method of coating the inorganic oxide particles with such an organophosphorus compound may be one in which the inorganic oxide particles and the organophosphorus compound are mixed together by a dry method or a wet method.

The amount of the organophosphorus compound is preferably from 1 to 25 parts by weight, and more preferably from 5 to 20 parts by weight, per 100 parts by weight of the inorganic oxide particles. At an amount below 1 part by weight, the desired properties may not be obtained. On the other hand, at an amount greater than 25 parts by weight, agglomeration of the inorganic oxide particles may arise, worsening their dispersibility.

The inorganic oxide particles are preferably silica particles, with hydrophobic spherical silica fine particles being especially preferred. When the inorganic oxide particles are silica fine particles that are spherical and also highly hydrophobic, the dispersibility of the glass powder increases, promoting thermal melting of the glass powder in the firing step following electrode pattern printing, and the fire-through properties improve, further promoting the bond strength between the solar cell electrode and the silicon substrate.

The term “spherical” as used here in connection with the organophosphorus compound-coated hydrophobic spherical silica fine particles of the invention means that the particles, when projected in two dimensions, have a circularity in the range of 0.8 to 1. Here, the “circularity” of a particle refers to the value expressed as: (peripheral length of true circle having an area equal to the area of the two-dimensional projected image of the actual particle)/(peripheral length of two-dimensional projected image of the actual particle).

### Method for Producing Oraanophosphorus Compound-Coated Hydrophobic Spherical Silica Fine Particles

Next, the method for producing the organophosphorus compound-coated hydrophobic spherical silica fine particles of the invention is described in detail. The organophosphorus compound-coated hydrophobic spherical silica fine particles of the invention can be obtained by the production process described below.

Synthetic silica fine particles are broadly divided according to the method by which they are produced into pyrogenic silica (fumed silica), VMC silica (VMC: vaporized metal combustion), wet silica, and sol -gel silica (the Stöber process). Of these, the sol -gel silica described below is preferred in this invention. The production process is a method for producing organophosphorus compound surface-coated hydrophobic spherical silica fine particles that includes the steps of:

(A1) obtaining a mixed-solvent dispersion of SiO₂ unit-containing hydrophilic spherical silica fine particles by hydrolyzing and condensing, within a mixture of a hydrophilic organic solvent and water and in the presence of a basic substance, a tetrafunctional silane compound of general formula (I) below

Si(OR³)₄ (I)

(wherein each R³ is independently a monovalent hydrocarbon group of 1 to 6 carbon atoms.), a partial hydrolyzate of the tetrafunctional silane compound, or a mixture thereof;

(A2) obtaining a mixed-solvent dispersion of hydrophobic spherical silica fine particles of a first type, referred to herein as “surface-hydrophobized spherical silica fine particles,” by adding to the mixed-solvent dispersion of hydrophilic spherical silica fine particles a trifunctional silane compound of general formula (II) below

R¹Si(OR⁴)₃ (II)

(wherein R is a substituted or un_substituted monovalent hydrocarbon group of 1 to 20 Carbon atoms, and each R⁴ is independently a monovalent hydrocarbon group of 1 to 6 carbon atoms), a partial hydrolyzate of the trifunctional silane compound, or a mixture thereof and surface-treating the hydrophilic spherical silica fine particles no as to introduce R¹SiO_{3/2} units (wherein R¹ in as defined above) onto surfaces of the hydrophilic spherical silica fine particles;

(A3) obtaining a concentrated mixed-solvent dispersion of the surface-hydrophobized spherical silica fine particles by removing part of the hydrophilic organic solvent and the water from, and thus concentrating, the mixed-solvent dispersion of surface-hydrophobized spherical silica fine particles;

(A4) obtaining hydrophobic spherical silica fine particles of a second type, referred to herein as “hydrophobic spherical silica fine particles,” by adding a silazane compound of general formula (III) below

R²₃SiNHSiR²₃ (III)

(wherein each R² is independently a substituted or unsubstituted monovalent hydrocarbon group of 1 to 6 carbon atoms), a monofunctional silane compound of general formula (IV) below

R²₃SiX (IV)

(wherein R² is as defined above, and X is a hydroxyl group or a hydrolyzable group), or a mixture thereof to the concentrated mixed-solvent dispersion of surface-hydrophobized spherical silica fine particles and treating the surface-hydrophobized spherical silica fine particles so as to introduce R²₃SiO_{1/2} units (wherein R² is as defined above) onto the surfaces of the surface-hydrophobized spherical silica fine particles; and

(A5) obtaining hydrophobic spherical silica fine particles of a third type, referred to herein as “organophosphorus compound-coated hydrophobic spherical silica fine particles,” by dissolving an organophosphorus compound in a dispersion of the hydrophobic spherical silica fine particles so as to at least partially surface-coat the hydrophobic spherical silica fine particles with the organophosphorus compound.

Hence, the surface-hydrophobized spherical silica fine particles of the invention are obtained by:
Step (A1): synthesis of hydrophilic spherical silica fine particles,
Step (A2): surface treatment with a trifunctional silane compound,
Step (A3): concentration,
Step (A4): surface treatment with a monofunctional silane compound, and
Step (A5): surface coating treatment with an organophosphorus compound.
   These steps are each described in order below.

### Step (A1): Synthesis of Hydrophilic Spherical Silica Fine Particles

In this Step, a mixed solvent dispersion of hydrophilic spherical silica fine particles is obtained by hydrolyzing and condensing, within a mixture of a hydrophilic organic solvent and water and in the presence of a basic substance, a tetrafunctional silane compound of general formula (I) below

Si(OR³)₄ (I)

(wherein each R³ is independently a monovalent hydrocarbon group of 1 to 6 carbon atoms), a partial hydrolyzate of the tetrafunctional silane compound, or a mixture thereof.

In general formula (I): Si(OR³)₄, R³ is a monovalent hydrocarbon group of 1 to 6 carbon atoms, and preferably an alkyl group of 1 to 4 carbon atoms, and especially 1 or 2 carbon atoms. Illustrative examples of the monovalent hydrocarbon group of R³ include methyl, ethyl, propyl, butyl and phenyl, with methyl, ethyl, propyl and butyl being preferred, and methyl and ethyl being especially preferred

Illustrative examples of the tetrafunctional silane compound of general formula (I): Si(OR³)₄ include tetraalkoxysilanes such as tetramethoxysilane, tetraethoxysilane, tetrapropoxysilare and tetrabutoxysilane, and also tetraphenoxysilane. Preferred examples include tetramethoxysilane, tetraethoxysilane, tetrapropoxysilane and tetrabutoxysilane, with tetramethoxysilane and tetraethoxysilane being especially preferred. Examples of partial hydrolytic condensates of the tetrafunctional silane compound of general formula (I) include methyl silicate and ethyl silicate.

The hydrophilic organic solvent is not particularly limited, provided it dissolves the tetrafunctional silane compound of general formula (I): Si(OR³)₄, partial hydrolytic condensates thereof and water. Illustrative examples include alcohols; cellosolves such as methyl cellosolve, ethyl cellosolve, butyl cellosolve and cellosolve acetate; ketones such as acetone and methyl ethyl ketone; and ethers such as dioxane and tetrahydrofuran. Preferred examples include alcohols and cellosolves; alcohols are especially preferred.

Examples of alcohols include those of general formula (V) below

R⁵OH (V)

wherein R⁵ is an alkyl or other monovalent hydrocarbon group of 1 to 6 carbon atoms.

In general formula (V): R⁵OH, R⁵ is monovalent hydrocarbon group of preferably 1 to 4 carbon atoms, and especially 1 or 2 carbon atoms. Illustrative examples of the monovalent hydrocarbon group represented by R⁵ include alkyl groups such as methyl, ethyl, propyl, isopropyl and butyl, with methyl, ethyl, propyl and isopropyl being preferred, and methyl and ethyl being more preferred. Illustrative examples of the alcohol of general formula (V) include methanol, ethanol, propanol, isopropanol and butanol, with methanol and ethanol being preferred. By increasing the number of carbon atoms on the alcohol, the particle size of the spherical silica fine particles that are produced increases. Therefore, methanol is preferred for obtaining the small-particle-size silica fine particles desired.

Examples of the basic substance include ammonia, dimethylamine and diethylamine. Preferred examples include ammonia and diethylamine, with ammonia being especially preferred. These basic substances are dissolved in the required amount in water, and the resulting aqueous solution (basic) may then be mixed together with the above hydrophilic organic solvent.

The amount of water used at this time is preferably from 0.5 to 5 moles, more preferably from 0.6 to 2 moles, and most preferably from 0.7 to 1 mole, per mole of the sum of the hydrocarbyloxy groups in the tetrafunctional silane compound of general formula (I): Si(OR³)₄ and/or partial hydrolytic condensates thereof. The ratio of the hydrophilic organic solvent to water, expressed as a weight ratio, is preferably from 0.5 to 10, more preferably from 3 to 9, and most preferably from 5 to 8. A larger amount of the hydrophilic organic solvent is more likely to result in the small-particle-size silica fine particles desired.

The amount of the basic substance is preferably from 0.01 to 2 moles, more preferably from 0.02 to 0.5 mole, and most preferably from 0.04 to 0.12 mole, per mole of the sum of the hydrocarbyloxy groups in the tetrafunctional silane compound of general formula (I): Si(OR³)₄ and/or partial hydrolytic condensates thereof. A smaller amount of the basic substance is more likely to result in the small-particle-size silica fine particles desired.

Hydrolysis and condensation of the tetrafunctional silane compound of general formula (I): Si(OR³)₄ is carried out by a commonly known method; that is, by adding the tetrafunctional silane compound of general formula (I) to a mixture of hydrophilic organic solvent and water that contains the basic substance.

The concentration of silica fine particles within the mixed-solvent dispersion of hydrophilic spherical silica fine particles obtained. in Step (A1) is generally from 3 to 15 wt %, and preferably from 5 to 10 wt %.

Step (A2): Surface Treatment with Trifunctional Silane Compound

A mixed-solvent dispersion of hydrophobic spherical silica fine particles of a first type., referred to herein as “surface-hydrophobized spherical silica fine particles,” is obtained by adding to the mixed-solvent dispersion of hydrophilic spherical silica fine particles obtained in Step (A1) a trifunctional silane compound of general formula (II) below

R¹Si(OR⁴)₃ (II)

(wherein R¹ is a substituted or unsubstituted monovalent. hydrocarbon group of 1 to 20 carbon atoms, and each R⁴ is independently a monovalent hydrocarbon group of 1 to 6 carbon atoms), a partial hydrolyzate of the trifunctional silane compound, or a mixture thereof and surface-treating the hydrophilic spherical silica fine particles so as to introduce R¹SiO_{3/2} units (wherein R¹ is as defined above) onto the surface of the hydrophilic spherical silica fine particles.

This step (A2) is essential for suppressing the agglomeration of silica fine particles in the next step: the concentration. Step (A3). When agglomeration cannot be suppressed, the individual particles of the resulting silica powder are unable to retain their primary particle size, and so coating of the surface by the organophosphorus compound becomes inadequate when the production process reaches Step (A5). Moreover, the hydrophobic spherical silica fine particles have a poor dispersibility when added to the conductive paste.

In general formula (II): R¹Si(OR⁴)₃, R¹ is a monovalent hydrocarbon group of generally 1. to 20 carbon atoms, preferably 1 to 3 carbon atoms, and most preferably 1 or 2 carbon atoms. Illustrative examples of the monovalent hydrocarbon group represented by R¹ include alkyl groups such as methyl, ethyl, n-propyl, isopropyl, butyl and hexyl; methyl, ethyl, n-propyl and isopropyl are preferred; methyl and ethyl are especially preferred. Some or all of the hydrogen atoms on these monovalent hydrocarbon groups may be substituted with halogen atoms such as fluorine, chlorine or bromine, of which fluorine is preferred.

In general formula (II): R¹Si(OR⁴)₃, R⁴ is a monovalent hydrocarbon group of generally 1 to 6 carbon atoms, preferably 1 to 3 carbon atoms, and most preferably 1 or 2 carbon atoms. Illustrative examples of the monovalent hydrocarbon group represented by R⁴ include alkyl groups such as methyl, ethyl, propyl and butyl; methyl, ethyl and propyl are preferred; methyl and ethyl are especially preferred.

Illustrative examples of the trifunctional silane compound of general formula (II): R¹Si(OR⁴), include trialkoxysilanes such as methyltrimethoxysilane, methyltriethoxysilane, ethyltrimethoxysilane, ethyltriethoxysilane, n-propyltrimethoxysilane, n-propyltriethoxysilane, isopropyitrimethoxysilane, isopropyltriethoxysilane, butyl trimethoxysilane, butvltriethoxysilane, hexyltrimethoxysilane, trifluoropropyitrimethoxysilane and heptadecafluorodecyltrimethoxysilane; methyltrimethoxysilane, methyltriethoxysilane, ethyltrimethoxysilane and ethyltriethoxysilane are preferred; methyltrimethoxysilane and methyltriethoxysilane are more preferred. Additional examples include partial hydrolytic condensates of these.

The trifunctional silane compound of general formula (II): R¹Si(OR⁴)₃ is added in an amount, per mole of silicon atoms in the hydrophilic spherical silica fine particles used, of generally from 0.001 to 1 mole, preferably from 0.01 to 0.1 mole, and especially from 0.01 to 0.05 mole. An addition amount of 0.001 mole or more is desirable because agglomeration of the silica fine particles is hardly to arise, in the case of concentration of the mixed-solvent dispersion of the surface -hydrophobized spherical silica fine particles in the next Step (A3). On the other hand, an amount of 1 mole or less is desirable because agglomeration of the silica fine particles does not arise.

In the mixed-solvent dispersion of surface-hydrophobized spherical silica fine particles obtained in this step (A2), the concentration of the silica fine particles is generally at least 3 wt % and less than 15 wt %, and preferably from 5 to 10 wt %. A concentration of 3 wt % or more is desirable because the productivity increases, and a concentration of less than 15 wt % is desirable because agglomeration of the silica fine particles does not arise.

### Step (A3): Concentration

A concentrated mixed-solvent dispersion of the surface-hydrophobized spherical silica fine particles is obtained by removing part of the hydrophilic organic solvent and water from, and thus concentrating, the mixed-solvent dispersion of the surface-hydrophobized spherical silica fine particles obtained in Step (A2). A hydrophobic organic solvent may be added at this time, either ahead of or during the step. The hydrophobic solvent used is preferably a hydrocarbon solvent or a ketone solvent. Illustrative examples include toluene, xylene, methyl ethyl ketone and methyl isobutyl ketone, with methyl isobutyl ketone being preferred. The method for removing part, of the hydrophilic organic solvent and water is exemplified by distillation and vacuum distillation. The resulting concentrated dispersion has a silica fine particle concentration of preferably from 15 to 40 wt %, more preferably from 20 to 35 wt %, and most preferably from 25 to 30 wt %. At a concentration at 15 wt % or more, surface treatment in the subsequent steps proceeds well. At a concentration of 40 wt % or less, agglomeration of the silica fine particles does not arise, which is highly desirable.

This step (A3) is essential for minimizing the following problems: the reaction with alcohol and water of the silazane compound of general formula (III) and the monofunctional silane compound of general formula (IV) used in the next Step (AA) as surface treatment agents, resulting in inadequate surface treatment; the subsequent occurrence of agglomeration when drying is carried out, making it impossible for the resulting silica powder to retain the primary particle size; and thus resulting in poor coating by the organophosphorus compound when the process moves on to Step (A5); and worsening of the dispersibility when the organophosphorus compound-coated hydrophobic spherical silica fine particles are added to the conductive paste.

Step (A4): Surface Treatment with Monofunctional Silane Compound

Hydrophobic spherical silica fine particles of a second type, referred to herein as “hydrophobic spherical silica. fine particles,” are obtained by adding a silazane compound of general formula (III) below

R²₃SiNHSiR²₃ (III)

(wherein each R² is independently a substituted or unsubstituted monovalent hydrocarbon group of 1 to 6 carbon atoms), a monofunctional silane compound of general formula (IV) below

R²₃SiX (IV)

(wherein R² is as defined above, and X is a hydroxyl group or a hydrolyzable croup), or a mixture thereof to the concentrated mixed-solvent dispersion of surface-hydrophobized spherical silica fine particles obtained in Step (A3), and treating the surface-hydrophobized spherical silica fine particles so as to introduce R²₃SiO_{1/2} units (wherein R² is as defined above) onto the surfaces of the surface-hydrophobized spherical silica fine particles. In this step, the foregoing treatment introduces R²₃SiO_{1/2} units onto the surfaces of the surface-hydrophobized spherical silica fine particles by triorganosilylating the silanol groups remaining on the particle surfaces. By hydrophobizing the surface in this step, coating with an organophosphorus compound in Step (A5) proceeds more easily.

In general formula (III): R²₃SiNHSiR²₃ and general formula (IV): R²₃SiX, R² is a monovalent hydrocarbon group of generally 1 to 6 Carbon atoms, preferably 1 to 4 carbon atoms, and especially 1 or 2 carbon atoms. Illustrative examples of monovalent hydrocarbon groups represented by R² include alkyl groups such as methyl, ethyl, propyl, isopropyl and butyl; methyl, ethyl and propyl are preferred; methyl and ethyl are especially preferred. Some or all of the hydrogen atoms on these monovalent hydrocarbon groups may be substituted with halogen atoms such as fluorine, chlorine or bromine, of which fluorine is preferred.

The hydrolyzable group represented by X in general formula (IV): R²₃SiX is exemplified by a chlorine atom, alkoxy groups, amino groups and acyloxy groups; alkoxy groups and amino groups are preferred; alkoxy groups are especially preferred.

The silazane compound of general formula (III): R²₃SiNHSiR²₃ is exemplified by hexamethyldisilazane and hexaethyldisilazane, with hexamethyldisilazane being preferred. The monofunctional silane compound of general formula (IV): R²₃SiX is exemplified by monosilanol compounds such as trimethylsilanol and triethylsilanol, monochlorosilanes such as trimethylchlorosilane and triethylchlorosilane, monoalkoxysilanes such as trimethylmethoxysilane and trimethylethoxysilane, monoaminosilanes such as trimethylsilyidimethylamine and trimethylsilyldiethylamine, and monoacyloxysilanes such as trimethylacetoxysilane. Of these, trimethylsilanol, trimethylmethoxysilane and trimethylsilyidiethylamine are preferred; trimethylsilanol and trimethylmethoxysilane are especially preferred.

The silazane compound and the monofunctional silane compound are used in amounts, per mole of silicon atoms in the hydrophilic spherical silica fine particles used, of generally from 0.1 to 0.5 mole, preferably from 0.2 to 0.4 mole, and most preferably from 0.25 to 0.35 mole. An amount of use of 0.1 mole or more is desirable because the efficiency of the surface coating treatment with an organophosphorus compound becomes well in the next Step (A5) by good dispersion state of the hydrophobic spherical silica fine particles. On the other hand, an amount of 0-5 mole or less is economically advantageous.

Step (A5): Surface Coating Treatment with Organophosphorus Compound

A dispersion of the hydrophobic spherical silica fine particles obtained in step (A4) is used directly as is, or the hydrophobic spherical silica fine particles are first dried to give a dry powder that is re-dispersed in a solvent to form a dispersion. The solvent used for dispersing the hydrophobic spherical silica fine particles may be any in which the organophosphorus compound to be used is soluble. The solvent is exemplified by various types of organic solvents, including ketone solvents such as acetone, methyl ethyl ketone and methyl isobutyl ketone., aliphatic hydrocarbons, aromatic hydrocarbons such as toluene and xylene, as well as derivatives thereof, alcohols, ester solvents, and cyclic ethers such as tetrahydrofuran (THF).

The concentration of the organophosphorus compound in this dispersion is set to preferably from 1 to 20 wt %, and more preferably from 2, to 10 wt %. The surface coating treatment conditions preferably involve the dropwise addition, to a dispersion of the silica fine particles, of the organophosphorus compound diluted and dispersed in solvent. Dropwise addition is carried out at preferably between 20 and 50° C., and more preferably between 20 and 40° C. The addition time is preferably from 10 minutes to 1 hour, and more preferably from 20 to 40 minutes. Following dropwise addition of the organophosphorus compound, stirring treatment is carried out at preferably 20 to 50° C. for 1 to 8 hours, and more preferably 20 to 40° C. for 2 to 6 hours.

After the hydrophobic spherical silica fine particles have been coated with the organophosphorus compound, the coated particles are dried by normal-pressure drying, vacuum drying or the like to give the organophosphorus compound-coated hydrophobic spherical silica fine particles of the invention.

The organophosphorus compound-coated hydrophobic spherical silica fine particles of the invention may be optionally surface treated with any of various silane coupling agents or with a silane such as dimethyldimethoxysilane.

### Preparation of Conductive Paste

The conductive paste of the invention contains electrically conductive particles, a glass powder, a binder, an organic solvent and the above-described organophosphorus compound-coated inorganic oxide particles. The content of the organophosphorus compound-coated inorganic oxide particles, based on the total amount of conductive paste, is from 0.1 to 7.0 wt %. At less than 0.1 wt %, the bonding strength during conductive connection is inadequate, lowering the reliability of the electrodes. On the other hand, at more than 7.0 wt %, the inorganic oxide particles occupy much of the electrode surface, hindering the deposition of the electrically conductive particles.

The conductive paste composition is preferably formulated as follows, based on a total amount of 100 wt % of the paste composition:
the electrically conductive particles described above:
   at least 50 wt % and not more than 95 wt %, and more preferably at least 80 wt % and not more than 95 wt %;
the glass powder described above:
   at least 0.5 wt % and not more than 5 wt %, and more preferably at least 1 wt % and not more than 3 wt %;
the organophosphorus compound-coated inorganic oxide described above:
   at least 0.1 wt % and not more than 7.0 wt %;
the binder described above:
   at least 0.1 wt % and not more than 10 wt %, and more preferably at least 1 wt % and not more than 3 wt %;
the organic solvent described above: balance.

This conductive paste composition can be prepared by mixing together the above ingredients.

For example, preparation of the conductive paste composition may be carried out as follows.

First, an organic vehicle is prepared by dissolving the binder in the organic solvent. The electrically conductive particles, glass powder and organophosphorus compound-coated inorganic oxide are charged into a kneader (it is desirable here to further increase the dispersibility of the glass powder by carrying out addition of the electrically conductive particles after thoroughly stirring the glass powder and the organophosphorus compound-coated inorganic oxide), and then are worked together while adding the organic vehicle a little at a time. Next, the resulting mixture is passed through a three-roll mill adjusted to the desired gap, thereby giving the conductive paste composition.

### Formation of Solar Cell Electrode

The conductive paste of the invention can be suitably used to form solar cell electrodes, especially electrodes on the n+ layer side of a solar cell.

A method referred to as the fire-through process may be used to form the solar cell electrode. Normally, an anti-reflective coating is formed on the light-receiving side of the solar cell. The electrode is formed by using, for example, a screen printing process to apply the conductive paste composition in a suitable shape onto the anti-reflective coating, and then carrying out firing treatment.

By adding organophosphorus compound-coated inorganic oxide particles, the dispersibility of the glass powder in the conductive paste of the invention improves, and a thermal melt-promoting effect is also obtained. As a result, even when glass powder having a high softening point is used, the fire-through properties improve without requiring much of an increase in the firing temperature, thus improving the power output of the solar cell. At the same time, sufficient bond strength is obtained between the electrode and the silicon substrate. Also, because of the phosphorus ingredient, the ohmic contact improves at the interface between the solar cell electrode and the silicon substrate n+ layer, enabling the power output of the solar cell to be further increased.

In general, when the firing temperature is lowered, melting of the glass powder proceeds only partially, resulting in a decrease in the fire-through properties and a decline in the bond strength with the silicon substrate, as a result of which the power output of the solar cell may decrease and sufficient bond strength between the electrode and the silicon substrate may not be obtained. However, with the method of the invention, owing to the glass powder thermal melt-promoting effect by the organophosphorus compound-coated inorganic oxide particles, even when the firing temperature is lowered, sufficient effects can be manifested in terms of the bonding properties between the electrode and the silicon substrate and in terms of the fire-through properties. Moreover, as a secondary effect, the toll on the silicon substrate of lowering the firing temperature decreases, raising the solar cell power output. The firing temperature in this case is preferably from 600 to 900° C., and especially from 700 to 900° C.

Hence, the method of the invention greatly expands the range of choice in glass powders and the desirable range in the firing temperature conditions.

### EXAMPLES

The invention is illustrated more fully below by way of Synthesis Examples, Working Examples and Comparative Examples, although these Examples are not intended to limit the invention in any way.

### Synthesis Example 1

### Synthesis of Organophosphorus Compound-Coated Hydrophobic Spherical Silica Fine Particles

### Step (A1): Synthesis of Hydrophilic Spherical Silica Fine Particles

A three-liter glass reactor equipped with a stirrer, a dropping funnel and a thermometer was charged with 989.5 g of methanol, 135.5 g of water and 66.5 g of 28 wt % ammonia water, and mixing was carried out. This solution was adjusted to 35° C., and 436.5 (2.87 moles) of tetramethoxysilane was added dropwise over 6 hours under stirring. Following the completion of addition, hydrolysis was carried out by continuing to stir for another 0.5 hour, thereby giving a suspension of hydrophilic spherical silica fine particles.

Step (A2): Surface Treatment with Trifunctional Silane Compound

Next, 4.4 g (0.03 mole) of methyltrimethoxysilane was added dropwise over 0.5 hour at 25° C. to the suspension, following which stirring was continued for 12 hours, thereby hydrophobically treating the surface of the silica fine particles and giving a hydrophobic spherical silica fine particle dispersion.

### Step (A3): Concentration

Next, an ester adapter and a condenser were fitted onto the glass reactor, the dispersion obtained in the preceding step was heated to 60 to 70° C., and 1.021 g of a mixture of methanol and water were distilled off, giving a concentrated mixed-solvent dispersion of the hydrophobic spherical silica fine particles. The content of hydrophobic spherical silica fine particles in the concentrated dispersion was 28 wt %.

Step (A4): Surface Treatment with Monofunctional Silane Compound

Hexamethyldisilazane (138.4 g, 0.86 mole) was added at 25° C. to the concentrated dispersion obtained in the preceding step, following which the dispersion was heated to 50 to 60° C. and reacted for 9 hours, thereby trimethylsilylating the silica fine particles in the dispersion. The solvent within this dispersion was then distilled off at 130° C. and under reduced pressure (6,650 Pa), giving 166 g of hydrophobic spherical silica fine particles.

Step (A5): Surface Coating Treatment with Organophosphorus Compound

Next, 200 g of methanol and 100 g of the hydrophobic spherical silica fine particles obtained in Step (A4) were added to a 0.5-liter glass reactor equipped with a stirrer, a dropping funnel and a thermometer, and mixing was carried out. While stirring this mixture, a solution of 10 g of Phosmer™ MH (Uni-Chemical Co., Ltd.) dissolved in 20 g of methanol was added dropwise at 25° C. over 30 minutes, and mixed at 25° C. for hours. The mixture was then dried, giving 109 g of organophosphorus compound-coated hydrophobic spherical silica fine particles.

The particle size of the hydrophilic spherical silica fine particles obtained in Step (A1) Was measured by the particle size measurement method below. In addition, the particle size measurement and shape observation described below were carried out on the organophosphorus compound-coated hydrophobic spherical silica fine particles obtained from above Steps (A1) to (A5). The results are shown in Table 1.

### [Particle Size Measurement]

A silica fine particle suspension or silica fine particle powder was added to methanol so as to give a silica fine particle content of 0.5 wt %, following which ultrasonic treatment was carried out for 10 minutes to disperse the fine particles. The particle size distribution of the fine particles thus treated was measured with a dynamic light scattering/laser Doppler Nanotrac™ particle size analyzer (trade name: UPA-EX150, from Nikkiso Co., Ltd.), and the resulting volume base median diameter ^{was} taken as the particle size. Here, “median diameter” refers to the 50% particle size in the cumulative size distribution.

### [Shape Observation]

The particle shapes were determined by carrying out observation with a Hitachi S-4700 electron microscope at a magnification of 100,000. When the particles were projected in two dimensions, those particles having a circularity in the range of 0.8 to 1 were designated as “spherical,” and all other particles were designated as “irregularly shaped.” Here, the “circularity” of a particle refers to the value expressed as: (peripheral length of true circle having an area equal to the of the two-dimensional projected image of the actual particle)/(peripheral length of two-dimensional projected image of the actual particle).

### Synthesis Example 2

Aside from changing the respective amounts of methanol, water and 28 wt % ammonia water in. Step (A1) to: methanol, 1,045.7 g; water, 112.6 g; and 28 wt % ammonia water, 33.2 g, the same procedure was carried out as in Synthesis Example 1, giving 104 g of organophosphorus compound-coated hydrophobic spherical silica fine particles. Table 1 shows the results of measurement carried out in the same way as in Synthesis Example 1 using the organophosphorus compound-coated hydrophobic spherical silica fine particles thus obtained.

### Synthesis Example 3

### Step (A-1)

Methanol (623.7 g), water (41.4 g) and 28 wt % ammonia water (49.8 g) were added to a three-liter glass reactor equipped with a stirrer, a dropping funnel and a thermometer, and were mixed together. The solution was then adjusted to 35° C., following which the dropwise addition under stirring of 1,153.7 g of tetramethoxysilane and of 418.1 g of 5.4 wt % ammonia water was begun at the same time, with the former being added over a period of 6 hours and the latter being added over 4 hours. Following the Completion of addition, stirring was continued for 0.5 hour, thereby giving a silica fine particle suspension.

### Step (A2)

Surface treatment of the Silica fine particles was carried out by the dropwise addition, at 25° C. and over 0.5 hour, of methyltrimethoxysilane in an amount of 11.6 g (corresponding to a molar ratio of 0.01 with respect to the tetramethoxysilane) to the resulting suspension, and 12 hours of stirring following addition.

### Step (A3)

An ester adapter and a condenser were fitted to the glass reactor and 1,440 g of methyl isobutyl ketone was added to the dispersion of surface-treated silica fine particles, following which the dispersion was heated to 80 to 110° C. and methanol water was distilled off over a period of 7 hours.

### Step (A4)

Next, 357.6 g of hexamethyldisilazane was added at 25° C. to the resulting dispersion, and the dispersion was heated to 120° C. and reacted for 3 hours, thereby trimethylsilylating the silica fine particles. The solvent was then distilled off under reduced pressure, giving 472 g of hydrophobic spherical silica fine particles.

### Step (A5)

Methanol (200 g) and 100 g of the hydrophobic spherical silica fine particles obtained in Step (A4) were charged into a 0.5-liter glass reactor equipped with a stirrer, a dropping funnel and a thermometer, and mixed together. While stirring this mixture, a solution of 10 g of Phosmer™ MH (Uni-Chemical Co., Ltd.) dissolved in 20 g of methanol was added dropwise, and mixing was carried out at 25° C. for 3 hours. The mixture was then dried, giving 109 g of organophosphorus compound-coated hydrophobic spherical silica fine particles. The results are shown in Table 1.

### Synthesis Example 4

Aside from changing the amount of Phosmer™ MH to 5 g, preparation was carried out ⁱⁿ the same way as in Synthesis Example 3, giving 104 g of organophosphorus compound-coated hydrophobic spherical silica fine particles. The results are shown in Table 1.

### Synthesis Example 5

Aside from changing the amount of Phosmer™ MH to 20 g, preparation was carried out in the same way as in Synthesis Example 3, giving 118 g of organophosphorus compound-coated hydrophobic spherical silica fine particles. The results are shown in Table 1.

### Comparative Synthesis Example 1

Hydrophobic spherical silica fine particles were obtained without carrying out Step (A5) in Synthesis Example 1. The results are shown in Table 1.

### Comparative Synthesis Example 2

Hydrophobic spherical silica fine particles were obtained without carrying out Step (A5) in Synthesis Example 2. The results are shown in Table 1.

### Comparative Synthesis Example 3

Hydrophobic spherical silica fine particles were obtained without carrying out Step (A5) in Synthesis Example 3. The results are shown in Table 1.

### Comparative Synthesis Example 4

Other than not adding hexamethyldisilazane and not carrying out the trimethylsilylation of silica fine particles in Step (A4), organophosphorus compound-coated silica particles were obtained in the same way as in Synthesis Example 1. The results are shown in Table 1.

### Comparative Synthesis Example 5

Other than not adding hexamethyldisilazane and not carrying out the trimethylsilyiation of silica fine particles in Step (A4), organophosphorus compound-coated silica particles were obtained in the same way as in Synthesis Example 2. The results are shown in Table 1.

### Comparative Synthesis Example 6

Other than not adding hexamethyldisilazane and not carrying out the trimethylsilylation of silica fine particles in Step (A4), organophosphorus compound-coated silica particles were obtained in the same way as in Synthesis Example 3. The results are shown in Table 1.

TABLE 1

| | Synthesis Example | | | | | Comparative Synthesis Example | | | | | |
|---|---|---|---|---|---|---|---|---|---|---|---|
| | 1 | 2 | 3 | 4 | 5 | 1 | 2 | 3 | 4 | 5 | 6 |
| Particle | 52 | 11 | 115 | 115 | 115 | 52 | 11 | 115 | 52 | 11 | 115 |
| size¹⁾ (nm) | | | | | | | | | | | |
| Particle | 70 | 24 | 133 | 124 | 128 | 60 | 19 | 123 | 4,690 | 3,860 | 7,510 |
| size (nm) | | | | | | | | | | | |
| Shape | spherical | spherical | spherical | spherical | spherical | spherical | spherical | spherical | irregular | irregular | irregular |
| Phosmer ™ MH | 10 | 10 | 10 | 5 | 20 | 0 | 0 | 0 | 10 | 10 | 10 |
| amount²⁾ | | | | | | | | | | | |

¹⁾Hydrophilic spherical silica fine particles in dispersion obtained in Step (A1)
²⁾Treatment amount (parts by weight) per 100 parts by weight of inorganic oxide particles

### Working Examples 1 to 5, Comparative Examples 1 to 7

Conductive paste compositions to which were respectively added the silica particles obtained in the above Synthesis Examples and Comparative Synthesis Examples were prepared.

A silver powder having an average particle size of 1 μm (available under the trade name AY6080 from Tanaka Kikinzoku Kogyo K. K.) was used as the electrically conductive particles This was added in an amount of 80 wt %, based on the overall conductive paste composition.

PbO-—B₂O₃—SiO₂ glass frit (available under the trade name ASF1340 from Asahi Glass Co., Ltd.) was used as the glass powder. This was added in an amount of 3 wt %, based on the overall conductive paste composition.

Ethyl cellulose was used as the binder, and α-terpineol was used as the solvent. A 10 wt % α-terpineol solution of ethyl cellulose was added in an amount of 16 wt %, based on the overall conductive paste composition.

The silica particles obtained in the Synthesis Examples and the Comparative Synthesis Examples were added in an amount of 1.0 wt %, based on the overall conductive paste composition.

The glass powder and silica particles were stirred and mixed together, following which the silver powder and the binder solution were added and mixed together, and the conductive paste composition was subsequently prepared on a three-roll mill.

The solar cell was fabricated by furnishing a commercially available 156 mm square p-type monocrystalline silicon substrate (substrate thickness, 200 μm) for solar cells, and carrying out acid etching treatment on the surface to form a texture. A phosphorus-containing solution was coated onto the light-receiving side and heat-treated to form an n+ diffusion layer, following which excess phosphorus glass was removed, the silicon substrate end faces were PN separated, and a 90 nm anti-reflective coating (SiN film) was formed by plasma CVD on the n+layer forming side.

The conductive paste composition prepared as described above Was then Coated to a thickness of 15 to 20 μm by screen printing onto both the anti-reflective coating and the opposite side (back side) of the silicon substrate.

Using a near-infrared high-speed firing furnace, the silicon substrate thus obtained was fired within an open-air atmosphere at 300° C. (10 seconds)→temperature rise (20 seconds)→peak temperature (840° C.) After reaching the peak temperature, the substrate was cooled to 100° C. (20 seconds), thereby forming an electrode by the fire-through process.

The I-V characteristics of these solar cells were measured using a solar simulator, and the maximum generated electric power and the fill factor (FF) were calculated.

Also, a 1.5 mm wide interconnector was placed against the bus bar electrode on the light-receiving side and thermally welded at 350° C. for 2 seconds using a soldering iron, following Which the bond strength between the electrode and the silicon substrate was measured by carrying out a peel test in the 90° direction. Weldability with the interconnector was visually rated (Good: bonding was good; Fair: partial bonding; NG: did not bond). These results are shown in Table 2.

TABLE 2

| | | | Bond | Inter- |
|---|---|---|---|---|
| | Inorganic oxide | Solar cell | strength | connector |
| | particles | FF | (N) | weldability |
| Comparative | None | 0.74 | 2.0 | Good |
| Example 1 | | | | |
| Working | Synthesis Example 1 | 0.77 | 4.2 | Good |
| Example 1 | | | | |
| Working | Synthesis Example 2 | 0.78 | 4.8 | Good |
| Example 2 | | | | |
| Working | Synthesis Example 3 | 0.78 | 4.4 | Good |
| Example 3 | | | | |
| Working | Synthesis Example 4 | 0.77 | 4.4 | Good |
| Example 4 | | | | |
| Working | Synthesis Example 5 | 0.78 | 5.2 | Good |
| Example 5 | | | | |
| Comparative | Comparative | 0.75 | 4.4 | Good |
| Example 2 | Synthesis Example 1 | | | |
| Comparative | Comparative | 0.75 | 4.8 | Good |
| Example 3 | Synthesis Example 2 | | | |
| Comparative | Comparative | 0.75 | 4.4 | Good |
| Example 4 | Synthesis Example 3 | | | |
| Comparative | Comparative | 0.78 | 4.2 | Fair |
| Example 5 | Synthesis Example 4 | | | |
| Comparative | Comparative | 0.77 | 4.0 | Fair |
| Example 6 | Synthesis Example 5 | | | |
| Comparative | Comparative | 0.77 | — | NG |
| Example 7 | Synthesis Example 6 | | | |

As shown in Table 2, relative to Comparative Example 1 (no addition of inorganic oxide particles), advantageous effects on the fill factors and bond strengths were confirmed for the five compositions prepared in Working Example 1 to 5.

In Comparative Examples 2 to 4 in which the inorganic oxide particles were not coated with a phosphorus ingredient, good results were obtained for the bond strength, but desirable effects were not observed for the fill factor. This indicates that the phosphorus ingredient has the effect of improving the ohmic contact with the n+ layer side of the solar cell.

Comparative Examples 5 and 6 showed improvements in the fill factor and the bond strength relative to when inorganic oxide particles were not added, but only partial welding of the cell electrode and the interconnector occurred. In Comparative Example 7, welding of the cell electrode and the interconnector did not occur; because the particle size was too large, the silica fine particles occupied much of the cell electrode surface and presumably hindered deposition of the electrically conductive particles.

Similar evaluations were carried out using conductive paste compositions in which the amount of Synthesis Example 1 silica powder added in Working Example 1 was varied (Working Examples 6 to 9, Comparative Examples 8 to 11). Those results are presented in Table 3.

TABLE 3

| | Synthesis Example 1 | | | |
|---|---|---|---|---|
| | inorganic oxide | | Bond | Inter- |
| | particles | Solar cell | strength | connector |
| | (amount added)³⁾ | FF | (N) | weldability |
| Comparative | 0 | 0.74 | 2.0 | Good |
| Example 1 | | | | |
| Comparative | 0.01 | 0.76 | 2.1 | Good |
| Example 8 | | | | |
| Comparative | 0.03 | 0.75 | 1.9 | Good |
| Example 9 | | | | |
| Working | 0.1 | 0.76 | 4.1 | Good |
| Example 6 | | | | |
| Working | 0.5 | 0.77 | 4.6 | Good |
| Example 7 | | | | |
| Working | 1.0 | 0.77 | 4.2 | Good |
| Example 1 | | | | |
| Working | 5.0 | 0.77 | 5.2 | Good |
| Example 8 | | | | |
| Working | 7.0 | 0.76 | 5.1 | Good |
| Example 9 | | | | |
| Comparative | 10.0 | 0.75 | 4.8 | Fair |
| Example 10 | | | | |
| Comparative | 20.0 | 0.70 | — | NG |
| Example 11 | | | | |

³⁾Amount added (wt %) based on overall conductive paste

As shown in Table 3, relative to Comparative Example 1 (no addition of inorganic oxide particles), advantageous effects on the fill factor and bond strength were confirmed in Working Examples 6 to 9.

With the addition of less than 0.1 wt %, the effects of addition are small, and improvements are not apparent in both the fill factor and the bond strength.

On the other hand, when the amount of inorganic oxide particles added, based on the overall conductive paste, was 10.0 wt % (Comparative Example 10), bonding between the cell electrodes and the interconnector was partial; when the amount of addition was 20.0 wt % (Comparative Example 11), the fill factor decreased, in addition to which there was a loss of bondability between the cell electrode and the interconnector. This appears to be due to a rise in the wire resistance of the electrode and a rise in contact resistance owing to the increase in silica particles. Also, because the inorganic oxide particles occupy much of the cell electrode surface, they presumably hinder the deposition of electrically conductive particles during welding of the interconnector.

In addition, Table 4 shows the results obtained when firing was carried out at varying firing peak temperatures in Working Example 1 (Working Examples 10 to 14), and when firing was carried out at varying firing peak temperatures in Comparative Example 1 (Comparative Examples 12 to 16).

TABLE 4

| | Amount of | | | | |
|---|---|---|---|---|---|
| | Synthesis | | | | |
| | Example 1 | | | | |
| | inorganic | | | Solar cell | |
| | oxide | | | maximum | |
| | particles | | Solar | electric | Bond |
| | added | Firing peak | cell | power | strength |
| | (wt %)⁴⁾ | temperature | FF | (ratio)⁵⁾ | (N) |
| Comparative | 0 | 740° C. | 0.71 | 0.92 | 0.4 |
| Example 12 | | | | | |
| Comparative | | 790° C. | 0.73 | 1.01 | 1.3 |
| Example 13 | | | | | |
| Comparative | | 815° C. | 0.74 | 1.02 | 1.6 |
| Example 14 | | | | | |
| Comparative | | 840° C. | 0.74 | 1.00 | 2.0 |
| Example 1 | | | | | |
| Comparative | | 865° C. | 0.75 | 0.99 | 2.6 |
| Example 15 | | | | | |
| Comparative | | 890° C. | 0.75 | 0.97 | 2.8 |
| Example 16 | | | | | |
| Working | 1.0 | 740° C. | 0.73 | 0.97 | 2.4 |
| Example 10 | | | | | |
| Working | | 790° C. | 0.76 | 1.02 | 3.9 |
| Example 11 | | | | | |
| Working | | 815° C. | 0.76 | 1.02 | 4.2 |
| Example 12 | | | | | |
| Working | | 840° C. | 0.77 | 1.01 | 4.2 |
| Example 1 | | | | | |
| Working | | 865° C. | 0.76 | 1.01 | 5.8 |
| Example 13 | | | | | |
| Working | | 890° C. | 0.76 | 0.97 | 6.3 |
| Example 14 | | | | | |

⁴⁾Amount added (wt %) based on overall conductive paste
⁵⁾Ratio with respect to arbitrary value of 1.0 for Comparative Example 1 (in which hydrophobic spherical silica fine particles were not added and the firing peak temperature was 840° C.)

As shown in Table 4, when the organophosphorus compound-coated inorganic Oxide particles of Synthesis Example 1 were added in an amount of 1.0 wt %, based on the overall conductive paste composition, the Solar cell maximum electric power and bond strength were retained even at a firing peak temperature of 790° C. Working Example 11). Even when the firing peak temperature was lowered to 740° C. (Working Example 10), a bond strength comparable with that in Comparative Example 1 (in which hydrophobic spherical silica fine particles were not added and the firing peak temperature was 840° C.) was maintained.

This is presumably because the organophosphorus compound-coated inorganic oxide particles promote melting of the glass powder and, owing to good fire-through properties, enable the glass to penetrate the anti-reflective coating at a low temperature, and also because the phosphorus ingredient enables a good ohmic contact with the silicon substrate n+ layer to be obtained.

From these results, the inventive method of forming a solar cell electrode enables an increased solar cell fill factor, an increased bond strength between the silicon substrate and cell electrodes, and an increased power output to be obtained.

Also, the bond strength between the silicon substrate and cell electrodes can be maintained even when the firing peak temperature is lowered, thus enabling the electric power of the solar cell to be increased.

Japanese Patent Application No. 2015-160562 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A conductive paste comprising electrically conductive particles, a binder, an organic solvent, a glass powder, and inorganic oxide particles that are at least partially surface-coated with an organophosphorus compound and have an average particle size for primary particles thereof, expressed as the volume base median diameter, of from 0.01 to 5 μm, the inorganic oxide particles being included in an amount of from 0.1 to 7.0 wt % based on the total weight of the conductive paste.

2. The conductive paste of claim 1, wherein the inorganic oxide particles are hydrophobic spherical silica fine particles.

3. The conductive paste of claim 1, wherein the inorganic oxide particles that are at least partially surface-coated with an organophosphorus compound are hydrophobic spherical silica fine particles which are obtained by hydrolytically condensing a tetrafunctional silane compound, a partial hydrolytic condensate of a tetrafunctional silicone compound, or a mixture thereof to form hydrophilic spherical silica. fine particles and introducing R¹SiO_{1/2} units, wherein R¹ is a substituted or unsubstituted monovalent hydrocarbon group of 1 to 20 carbon atoms, and R²₃SiO_{1/2} units, wherein each R² is independently a substituted or unsubstituted monovalent hydrocarbon group of 1 to 6 carbon atoms, onto surfaces of the hydrophilic spherical silica fine particles, and which are, at least partially surface-coated with an organophosphorus compound.

4. The conductive paste of claim 1 for use in fabricating a solar cell electrode.

5. A method for preparing a conductive paste, the method being characterized by producing hydrophobic spherical silica fine particles that are at least partially surface-coated with an organophosphorus compound and have an average particle size for primary particles thereof, expressed as the volume base median diameter, of from 0.01 to 5 μm, and mixing the organophosphorus compound-coated hydrophobic spherical silica fine particles, in an amount of from 0.1 to 7.0 wt % based on the total weight of the conductive paste, together with conductive particles, a binder, an organic solvent and a glass powder, wherein the organophosphorus compound-coated hydrophobic spherical silica fine particles are produced by a method comprising the steps of:
(A1) obtaining a mixed-solvent dispersion of SiO₂ unit-containing hydrophilic spherical silica fine particles by hydrolyzing and condensing, within a mixture of a hydrophilic organic solvent and water and in the presence of a basic substance, a tetrafunctional silane compound of general formula (I) below
Si(OR³)₄ (I),
wherein each R³ is independently a monovalent hydrocarbon croup of 1 to 6 carbon atoms, a partial hydrolyzate of the tetrafunctional silane compound, or a mixture thereof;
(A2) obtaining a mixed-solvent dispersion of hydrophobic spherical silica fine particles of a first type, referred to herein as “surface -hydrophobized spherical silica fine particles,” by adding to the mixed-solvent dispersion of hydrophilic spherical silica fine particles a trifunctional silane compound of general formula (II) below
R¹Si(OR⁴)₃ (II),
wherein R¹ is a substituted or unsubstituted monovalent hydrocarbon group of 1 to 20 carbon atoms and each R² is independently a monovalent hydrocarbon group of 1 to 6 carbon atoms, a partial hydrolyzate of the trifunctional silane compound, or a mixture thereof and surface-treating the hydrophilic spherical silica fine particles so as to introduce R¹SiO_{3/2} units, wherein R¹ is as defined above, onto surfaces of the hydrophilic spherical silica fine particles;
(A3) obtaining a concentrated mixed-solvent dispersion of the surf ace-hydrophobized spherical silica fine particles by removing part of the hydrophilic organic solvent and the water from, and thus concentrating, the mixed-solvent dispersion of surface -hydrophobized spherical silica fine particles;
(A4) obtaining hydrophobic spherical silica fine particles of a second type, referred to herein as “hydrophobic spherical silica fine particles, ” by adding a silazane compound of general formula (III) below
R²₃SiNHSiR²₃ (III),
wherein each R² is independently a substituted or unsubstituted monovalent hydrocarbon group of 1 to 6 carbon atoms, a monofunctional silane compound of general formula (IV) below
R²₃SiX (IV),
wherein R² is as defined above and X is a hydroxyl group or a hydrolyzable group, or a mixture thereof to the concentrated mixed-solvent dispersion of surface-hydrophobized spherical silica fine particles and treating the surface-hydrophobized spherical silica fine, particles so as to introduce R²₃SiO_{1/2} units, wherein R³ is as defined above, onto the surfaces of the surf ace-hydrophobized spherical silica fine, particles.; and
(A5) obtaining hydrophobic spherical silica fine particles of a third type, referred to herein as “organophosphorus compound-coated hydrophobic spherical silica fine particles,” by dissolving an organophosphorus compound in a dispersion of the hydrophobic spherical silica fine particles so as to at least partially surface-coat the hydrophobic spherical silica fine particles with the organophosphorus compound.

6. A solar cell electrode comprising a fired body of the conductive paste for use in fabricating a solar cell electrode of claim 4.
